(19) United States
(12) Patent Application Publication
(10) Pub. No.: US 2009/0087993 A1
(43) Pub. Date: Apr. 2, 2009

(54) METHODS AND APPARATUS FOR COST-EFFECTIVELY INCREASING FEATURE DENSITY USING A MASK SHRINKING PROCESS WITH DOUBLE PATTERNING

(76) Inventor: Steven Maxwell, Sunnyvale, CA (US)

Correspondence Address: DUGAN & DUGAN, PC, 245 Saw Mill River Road, Suite 309, Hawthorne, NY, 10532, US

(21) Appl. No.: 11/864,901

(22) Filed: Sep. 28, 2007

(51) Int. Cl. H01L 21/311

(52) U.S. Cl. 438/703; 257/E21.249

(57) ABSTRACT

Methods and apparatus are provided for forming an array of devices. The invention includes forming a stack of material layers, forming a first hardmask over the plurality of material layers, exposing the first hardmask to ozone mixed with a halogenated additive, forming a protective layer over the first hardmask, forming a second mask on the protective layer shifted relative to the first mask, exposing the second hardmask to ozone mixed with the halogenated additive, and etching the plurality of material layers to remove material not covered by the hardmasks. Numerous other aspects are disclosed.

### CROSS REFERENCE TO RELATED APPLICATIONS

The present application is related to the following patent application, which is hereby incorporated by reference herein in its entirety for all purposes:

U.S. patent application Ser. No. 6,952,030, issued to Herner et al., filed May 26, 2004, and entitled “High-density three-dimensional memory cell.”

### FIELD OF THE INVENTION

The present invention relates to semiconductor manufacturing techniques and more particularly to cost-effectively increasing feature density using a mask shrinking process with double patterning.

### BACKGROUND OF THE INVENTION

Integrated circuits continue to follow Moore's Law in that the density of devices that may be formed on a chip continues to double every two years. Present manufacturing facilities routinely produce circuits with 130 nm, 90 nm, and even 65 nm feature sizes, and future facilities are expected to produce devices with even smaller feature sizes.

The continued reduction in device geometries has generated a demand for methods of forming nanometer sized features that are separated by nanometer sized distances. As the limits of optical resolution are being approached in current lithography processes, one method that has been developed to reduce the distance between features or devices on a substrate includes a double patterning of a hardmask layer that is used to transfer a pattern into the substrate. In the double patterning method, a hardmask layer is deposited on a substrate layer that is to be etched. The hardmask layer is patterned by photoresist deposited on the hardmask layer. The photoresist is then removed, and a second pattern is introduced into the hardmask layer with a second photoresist that is deposited on the hardmask layer.

However, as feature size and pitch is further reduced, the limits of optical resolution are exceeded even using the double patterning technique described above. Thus, while prior art double patterning methods can be used to reduce the size of, and distance between, features on a substrate using 130 nm process technology, light reflection and refraction limits the maximum resolution of such lithography techniques used with smaller process technology. Thus, what is needed are new methods that allow feature density to be increased without requiring optical resolution limits to be exceeded.

### SUMMARY OF THE INVENTION

In some aspects of the invention, a method is provided that includes forming a first hardmask at a maximum feature density of a process technology; shrinking the first hardmask; forming a second hardmask at the maximum feature density laterally shifted relative to the first hardmask; shrinking the second hardmask; and forming at least a portion of a memory array using the first and second hardmasks.

In some aspects of the invention, a method is provided that includes forming a first mask over device layers; shrinking the first mask; forming a protective layer over the first mask; forming a second mask shifted relative to the first mask; and shrinking the second mask.

In some aspects of the invention, a method is provided that includes forming a first hardmask over a plurality of device layers; exposing the first hardmask to ozone mixed with a halogenated additive; forming a protective layer over the first hardmask; forming a second hardmask on the protective layer shifted relative to the first hardmask; and exposing the second hardmask to ozone mixed with the halogenated additive.

In some aspects of the invention, a method is provided for forming an array of devices. The method includes forming a stack of a plurality of material layers; forming a first hardmask over the plurality of material layers; exposing the first hardmask to ozone mixed with a halogenated additive; forming a protective layer over the first hardmask; forming a second mask on the protective layer shifted relative to the first mask; exposing the second hardmask to ozone mixed with the halogenated additive; and etching the plurality of material layers to remove material not covered by either hardmask.

In some aspects of the invention, memory arrays formed using the above methods are provided. Other features and aspects of the present invention will become more fully apparent from the following detailed description, the appended claims and the accompanying drawings.

### BRIEF DESCRIPTION OF THE DRAWINGS

FIGS. 1A to 1L are a sequence of cross-sectional views of a substrate with various process layers, the sequence representing steps for forming a memory element in accordance with the present invention.

FIGS. 2A to 2L are a sequence of cross-sectional views of a substrate with various process layers, the sequence representing steps for forming a conductor in accordance with the present invention.

### DETAILED DESCRIPTION

The present invention provides a cost-effect means of reducing the minimum feature size and pitch that a given process technology may achieve. For example, the present invention may be used to create approximately 45 nm features using 90 nm process technology or approximately 32 nm features using 65 nm process technology.

According to the present invention, a first mask layer is patterned; a novel process to thin or “shrink” the dimensions of individual elements or features of the first mask is applied (e.g., the pitch or space between lines of the mask is increased by narrowing the width of the lines themselves); a protective layer is applied over the shrunken first mask; a second mask is patterned on the protective layer but shifted relative to the first mask; the second mask is shrunk using the novel process; and then the unmasked areas are etched away to form the reduced size features.

By controllably reducing or shrinking the width of lines of a mask, the present invention effectively enables additional mask lines to be inserted between the original lines to create a mask with lines having widths and pitches that are approximately half the minimum nominal widths and pitches of the process technology (e.g., 32 nm, 65 nm, 80 nm, 90 nm process) being employed. Likewise, by controllably reducing the size of individual two-dimensional areas or features of a mask, the present invention effectively enables additional two-dimensional mask areas (e.g., features) to be inserted between the original areas to create a mask with mask areas having dimensions and pitches that are approximately half the minimum nominal widths and pitches of the process technology being used. Therefore, embodiments of the present invention effectively enables approximately doubling feature density. Note that, as used herein and unless otherwise specified, the term “shrinking” is intended to refer to reducing the dimensions of individual mask features and not necessarily to reducing the overall size of a mask.

In some embodiments, the present invention may be used to further controllably shrink hardmask material so that features of even smaller sizes may be created and multiple additional features inserted between the reduced size features. In other words, for example, instead of only shrinking hardmask features by approximately 50%, the methods of the present invention may be used to shrink features of a hardmask to 20% of their original size. Thus, instead of having room for only a single additional feature between the elements of the first pattern, two or more additional features may be formed between each of the shrunken hardmask elements. In some embodiments, triple or multiple patterning may be employed to implement inserting multiple hardmask elements between the initial shrunken hardmask elements. Therefore, the present invention may effectively enable approximately tripling, quadrupling, quintupling, etc. feature density. Likewise, the more the pattern features of a hardmask are shrunk, the more room will be available for additional hardmask pattern features to be inserted.

In some embodiments, the present invention may be employed to pattern approximately 45 nm wide diode pillars approximately 45 nm apart using 80 nm process technology. In other embodiments, the present invention may be employed to pattern approximately 45 nm wide conductor lines with an approximately 45 nm pitch using 80 nm process technology. In some embodiments, the controlled shrinking of the masks may be achieved by exposing the masks to ozone mixed with a halogenated additive solution (e.g., a dilute mixture of hydrofluoric acid (HF) in water). Thus, for example, fluorozone may be used to shrink a polysilicon hardmask that was initially formed with approximately 80 nm wide elements that are approximately 80 nm apart to a mask with approximately 45 nm wide elements that are approximately 160 nm apart, creating room for inserting an additional hardmask element. Thus, in some embodiments, the feature size of the hardmasks may be reduced to approximately 35% to approximately 65% of the original size and the feature pitch may be increased by approximately 70% to approximately 130%.

As indicated above, the mask shrinking may be performed in a two step process using double patterning to accurately locate the second mask between the shrunken elements of the first mask. Note that prior art techniques that use double patterning either require features in the photoresist to have a width that is the same size as the width of the final features of the devices on the substrate, rely on methods of shrinking photoresist instead of a hardmask, or require the use of relatively costly immersion lithography technology.

### Diode Array Forming Process

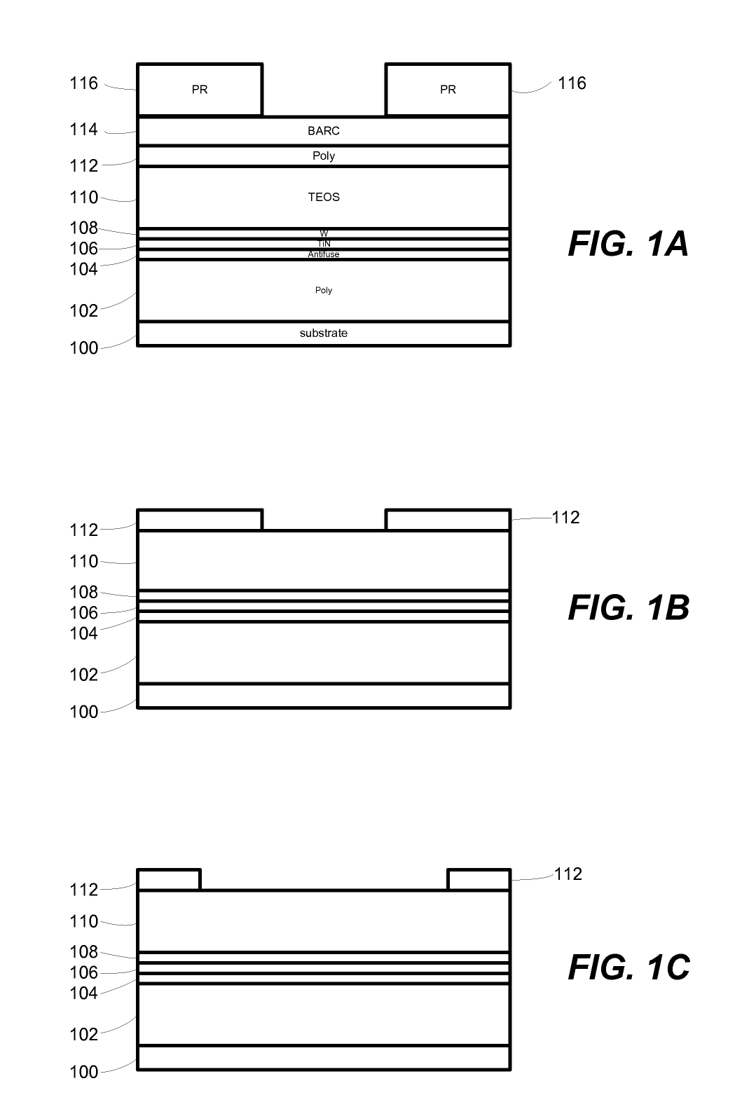

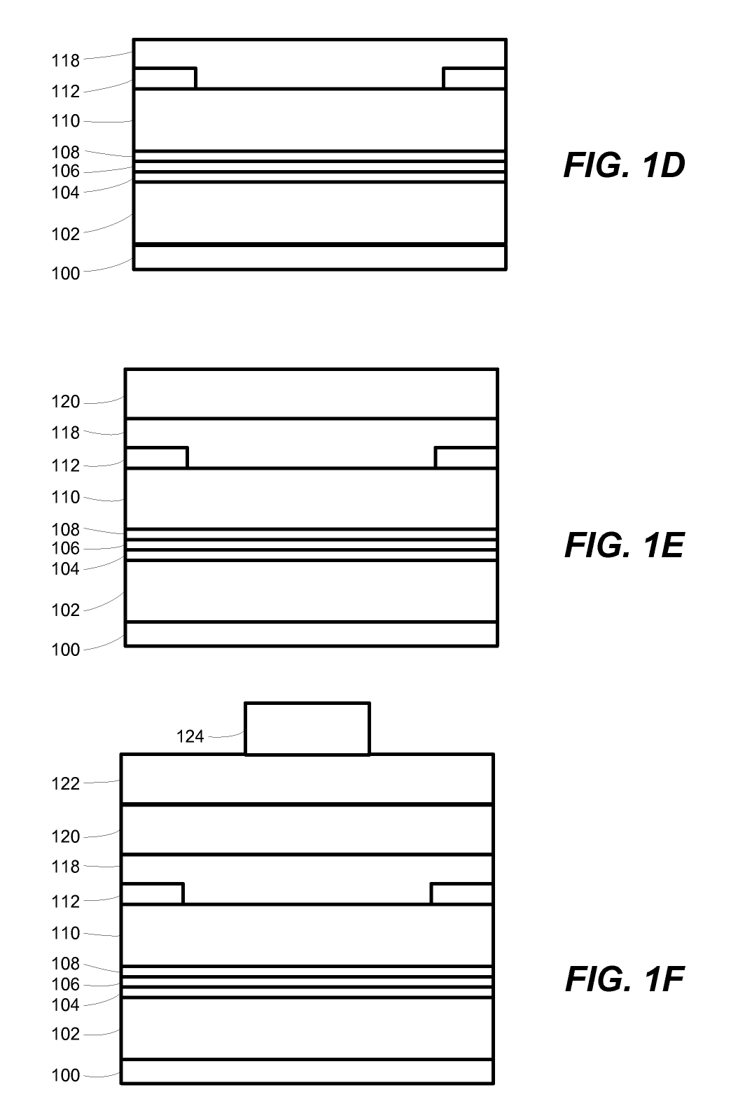

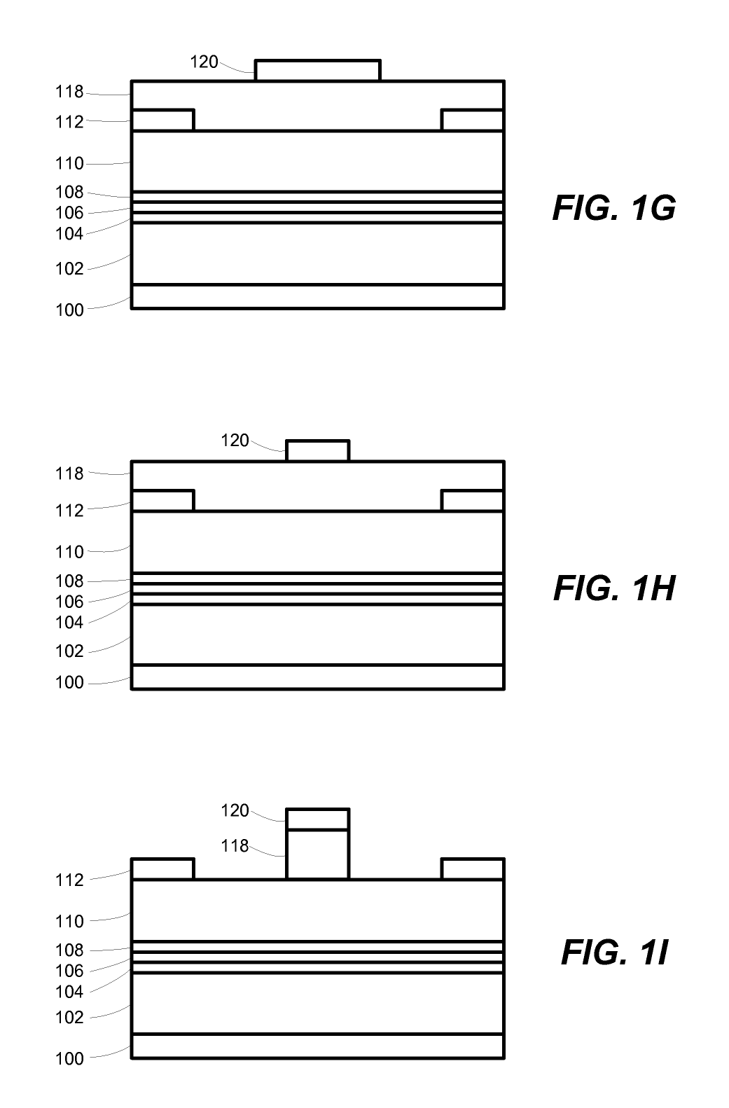

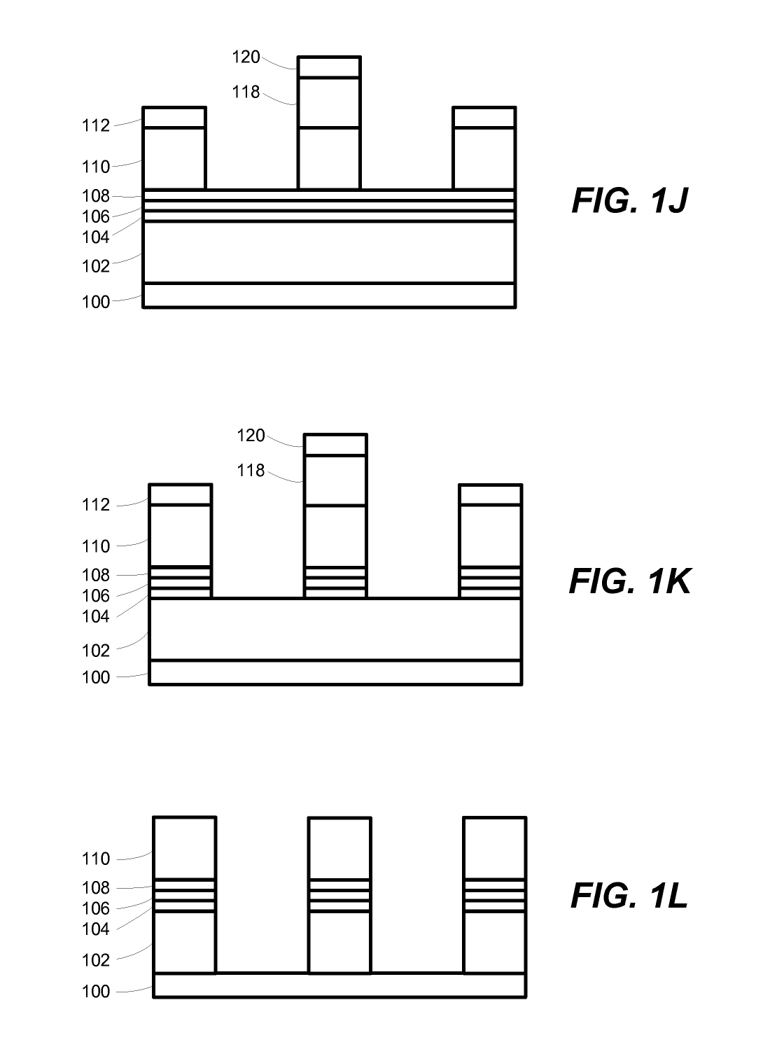

Turning now to FIGS. 1A through 1L, an example process for creating an array of diode pillars (e.g., for use in a three dimensional memory array) with an increased feature density is illustrated. Note that the drawings represent only a partial cross-sectional side view of only a small portion of a substrate with material layers that may be used to form one level of a three-dimensional memory array. In other words, even though formation of only one row of three diode pillars are depicted, the present invention may be applied to forming any number of rows of any number of diode pillars. Also note that while the process is illustrated as being performed on a substrate, the same process may be performed on top of one or more memory array levels so that additional levels of the memory array may be created by the process of the present invention.

With reference to FIG. 1A, a substrate 100 may be coated with multiple layers of films (e.g., polysilicon 102, an antifuse material 104, tantalum nitride (TiN) 106, tungsten (W) 108, etc.) that may ultimately be employed to form diode pillars. Previously incorporated U.S. patent application Ser. No. 6,952,030 describes various methods of forming such layers. Although only one level or series of layers is depicted, the present invention may be applied to multiple levels of layers used to form a monolithic three dimensional memory array. A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in U.S. Pat. No. 5,915,167, issued to Leedy, and entitled “Three dimensional structure memory,” which is incorporated herein by reference. The substrates may be thinned or removed from the memory levels before bonding, but as the memory levels are initially formed over separate substrates, such memories are not true monolithic three dimensional memory arrays.

Thus, in addition to layers that include materials to form diode pillars, layers that are used to form conductors (not shown) and insulators (not shown) may also be present on or between the levels of layers. Further the layers may be inverted as compared to the layers depicted in FIG. 1A. Finally, it should be understood that many additional and alternative layers of different materials and thicknesses may be used to form the levels.

A layer of tetraethyl orthosilicate 110 or Si(OC₂H₅)₄ (hereinafter “TEOS”) may be formed on the diode films. The TEOS layer 110 may have a thickness in the range of approximately 500 angstroms to approximately 4000 angstroms depending on the thickness of the stack of the diode films. Other materials such as SOG (spin on glass) and amorphous carbon may be used in place of TEOS.

On the TEOS layer 110, a layer of hardmask material 112 may be deposited. In some embodiments, a polycrystalline semiconductor material may be used as a hardmask 112 such as polysilicon, a polycrystalline silicon-germanium alloy, polygermanium or any other suitable material. In other embodiments, a material such as tungsten (W) may be used. The hardmask material layer 112 thickness may be of varying thickness, depending on the shrinking process parameters described below. In other words, in some embodiments, the hardmask material layer 112 may have an initial thickness in the range of approximately 500 angstroms to approximately 3000 angstroms depending on, for example, the concentrations of the components of the fluorozone process to be used.

To pattern the hardmask layer 112, photolithography layers such as Bottom Anti-Reflection Coating (BARC) 114 and patterned photoresist 116 may be deposited on the hardmask layer 112. The depths of the BARC 114 and photoresist 116 layers may be in the range of approximately 100 angstroms to approximately 2000 angstroms depending on the lithography process. Other resist or photolithography layers practicable and suitable for patterning the selected hardmask material 112 may be used.

According to the present invention, the photoresist 116 may be patterned using the highest feature density achievable with the process technology being used. Thus, if for example, 80 nm technology is used, the width of the elements of the photoresist pattern for forming features (e.g., diode pillars) may be 80 nm and the pitch, or spacing between the elements of the photoresist pattern, may also be 80 nm. Likewise, if 65 nm technology is used, the width of the elements of the photoresist pattern for forming features may be 65 nm and the pitch may also be 65 nm. Note that this is in contrast to convention double patterning methods where elements of the first photoresist pattern are required to be spaced apart further than the maximum density (e.g., minimum pitch) of the process technology being used.

Turning to FIG. 1B, a BARC/hardmask etch process applied to the structure in FIG. 1A results in the transfer of the photoresist pattern 116 to the hardmask 112. Any suitable BARC/hardmask etch process may be used. Many such processes are known in the art and thus, these processes are not described here.

Turning to FIG. 1C, the controlled shrinking of the hardmask 112 is achieved by exposing the patterned hardmask 112 to ozone mixed with a halogenated additive solution (e.g., a dilute mixture of hydrofluoric acid (HF) in water). Thus, for example, fluorozone may be used to shrink a polysilicon hardmask 112 that was initially formed with approximately 80 nm wide elements that are approximately 80 nm apart to a mask with approximately 45 nm wide elements that are approximately 160 nm apart, leaving room for inserting additional hardmask elements.

In some embodiments, fluorozone suitable for controllably shrinking hardmask materials may be formed using dilute hydrofluoric acid having a concentration in the range of approximately 0.03 Wt. % to approximately 0.2 Wt %. The ozone flow rate may be in the range of approximately 1 LPM to approximately 5 LPM with an O₃ concentration in the range of approximately 100 ppm to approximately 300 ppm. In some embodiments the dilute hydrofluoric acid may be heated to a temperature in the range of approximately 18° C. to approximately 35° C. The fluorozone process may be performed, for example, in a Raider® spray acid chamber manufactured by SemiTool Inc. of Kalispell, Mont. operating within a range of approximately 300 rpm to approximately 600 rpm. As indicated above, the initial hardmask 112 thickness may be of varying thickness, depending on the fluorozone process parameters. Also as indicated above, the controlled shrinking of the hardmask may be performed to reduce the hardmask's feature size by approximately 50%. This may be achieved by exposing the hardmask to the fluorozone process for a time in the range of approximately 5 seconds to approximately 0.25 hours. Further, in some embodiments, additional shrinkage may be achieved through longer exposure to the fluorozone process. In some embodiments, any native oxide on the surface of the hardmask may been removed prior to or during the exposure of the hardmask material to fluorozone.

Turning to FIG. 1D, an encapsulating or protective layer 118 may be deposited on the shrunken hardmask 112 to create a planarized surface upon which additional hardmask features may be formed. The protective layer 118 may include tantalum nitride, tungsten nitride, high-density plasma (HDP) oxide, TEOS, and/or spin-on-glass (SOG). The depth of the protective layer 118 may be in the range of approximately 200 angstroms to approximately 10,000 angstroms depending on the dimensions of layer 112.

Turning now to FIG. 1E, an additional layer of hardmask material 120 is deposited on the protective layer 118. This additional layer of hardmask material 120 will be used to form the additional feature (and, in some embodiments, multiple features) between the two original hardmask features. As with the first hardmask layer 112, a polycrystalline semiconductor material such as polysilicon, a polycrystalline silicon-germanium alloy, polygermanium or any other suitable material may be used as the hardmask 120. In other embodiments, a material such as tungsten (W) may be used. The hardmask material layer 120 thickness may be of varying thickness, depending on the subsequent shrinking process parameters. In other words, in some embodiments, the hardmask material layer 120 may be deposited with an initial thickness in the range of approximately 500 angstroms to approximately 3000 angstroms depending on, for example, the concentrations of the components of the fluorozone process to be used.

Turning now to FIG. 1F, to pattern the hardmask layer 120, photolithography layers such as BARC 122 and patterned photoresist 124 may be deposited on the hardmask layer 120. The depths of the BARC 122 and photoresist 124 layers may be in the range of approximately 100 angstroms to approximately 2000 angstroms depending on the lithography process. Other resist or photolithography layers practicable and suitable for patterning the selected hardmask material 120 may be used. Note that the patterned photoresist 124 may be patterned using the original lithography mask used to pattern the prior layer of photoresist 116. In some embodiments, the original lithography mask may simply be laterally shifted an amount approximately equal to the nominal size of the process technology being used. Thus, if an 80 nm process is being employed, the lithography mask may be shifted by approximately 80 nm to properly locate the additional hardmask features between the original hardmask features.

Turning to FIG. 1G, a BARC/hardmask etch process applied to the structure in FIG. 1F results in the transfer of the photoresist pattern 124 to the hardmask 120. As above, any suitable BARC/hardmask etch process may be used. Many such processes are known in the art and thus, these processes are not described here.

Turning to FIG. 1H, the controlled shrinking of the hardmask 120 may be achieved in the same manner as described above. By exposing the patterned hardmask 120 to ozone mixed with a halogenated additive solution (e.g., a dilute mixture of hydrofluoric acid (HF) in water) the hardmask 120 features may be shrunk. Fluorozone may be used to shrink a polysilicon or tungsten hardmask 120 that was initially formed with approximately 80 nm wide elements that are approximately 80 nm apart to a mask with approximately 45 nm wide elements that are approximately 160 nm apart.

As above, in some embodiments, fluorozone suitable for controllably shrinking hardmask materials may be formed using dilute hydrofluoric acid having a concentration in the range of approximately 0.03 Wt. % to approximately 0.2 Wt %. The ozone flow rate may be in the range of approximately 1 LPM to approximately 5 LPM with an O₃ concentration in the range of approximately 100 ppm to approximately 300 ppm. In some embodiments the dilute hydrofluoric acid may be heated to a temperature in the range of approximately 18° C. to approximately 35° C. The fluorozone process may be performed, for example, in a Raider® spray acid chamber manufactured by SemiTool Inc. of Kalispell, Mont. operating within a range of approximately 300 rpm to approximately 600 rpm. As indicated above, the initial hardmask 120 thickness may be of varying thickness, depending on the fluorozone process parameters. Also as indicated above, the controlled shrinking of the hardmask may be performed to reduce the hardmask's feature size by approximately 50%. This may be achieved by exposing the hardmask to the fluorozone process for a time in the range of approximately 5 seconds to approximately 0.25 hours. Further, in some embodiments, additional shrinkage may be achieved through longer exposure to the fluorozone process. In some embodiments, any native oxide on the surface of the hardmask may been removed prior to or during the exposure of the hardmask material to fluorozone.

Going from FIG. 1H to FIG. 1I, the protective layer 118 is etched out between the hardmask 112, 120 features down to the TEOS 110 layer in an oxide etch process. Going from FIG. 1I to FIG. 1J, the TEOS 110 layer is etched out between the hardmask 112, 120 features down to the top of diode layers (e.g., tungsten 108). Going from FIG. 1J to FIG. 1K, the tungsten 108, tantalum nitride 106, and antifuse 104 layers (or in other embodiments, alternative diode, memory cell, or circuit component materials) are etched out between the hardmask 112, 120 features. Going from FIG. 1K to FIG. 1L, the polysilicon layer 102 is etched out between the hardmask 112, 120 features and the hardmask 112, 120 is also etched away along with the remaining protective layer 118. The resulting structure is an array of diode pillars suitable for use in a memory array.

Although not shown, in some embodiments, after the diode pillar array has been formed, a dielectric layer may be deposited over the substrate 100 so as to fill the voids between the diode pillars. For example, approximately 200 to approximately 7000 angstroms of silicon dioxide may be deposited on the substrate 100 and planarized using chemical mechanical polishing or an etchback process to form a planar surface. Other dielectric materials such as silicon nitride, silicon oxynitride, low K dielectrics, etc., and/or other dielectric layer thicknesses may be used. Exemplary low K dielectrics include carbon doped oxides, silicon carbon layers, or the like.

### Conductor Array Forming Process

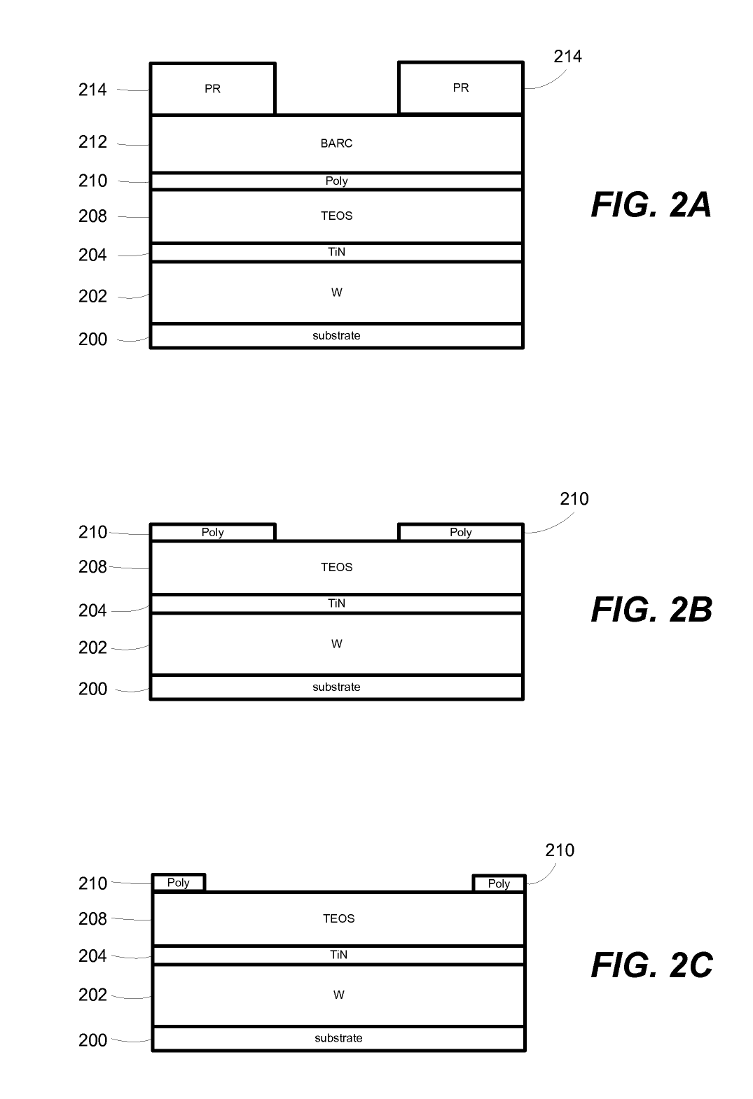

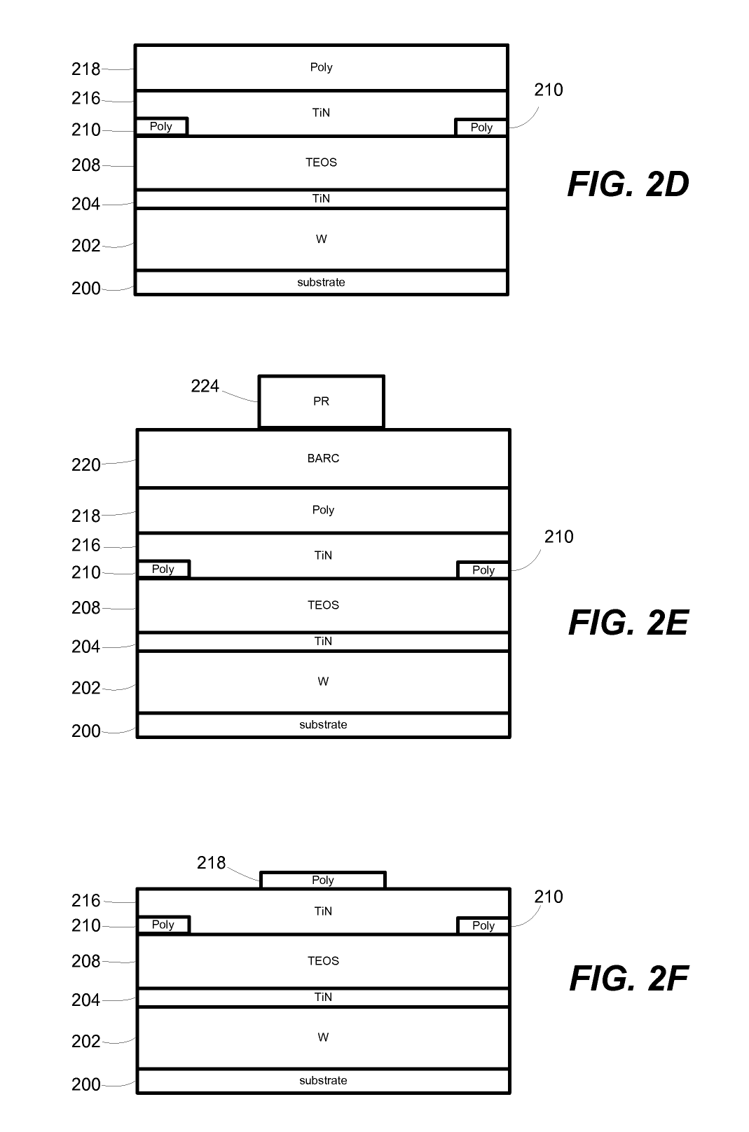

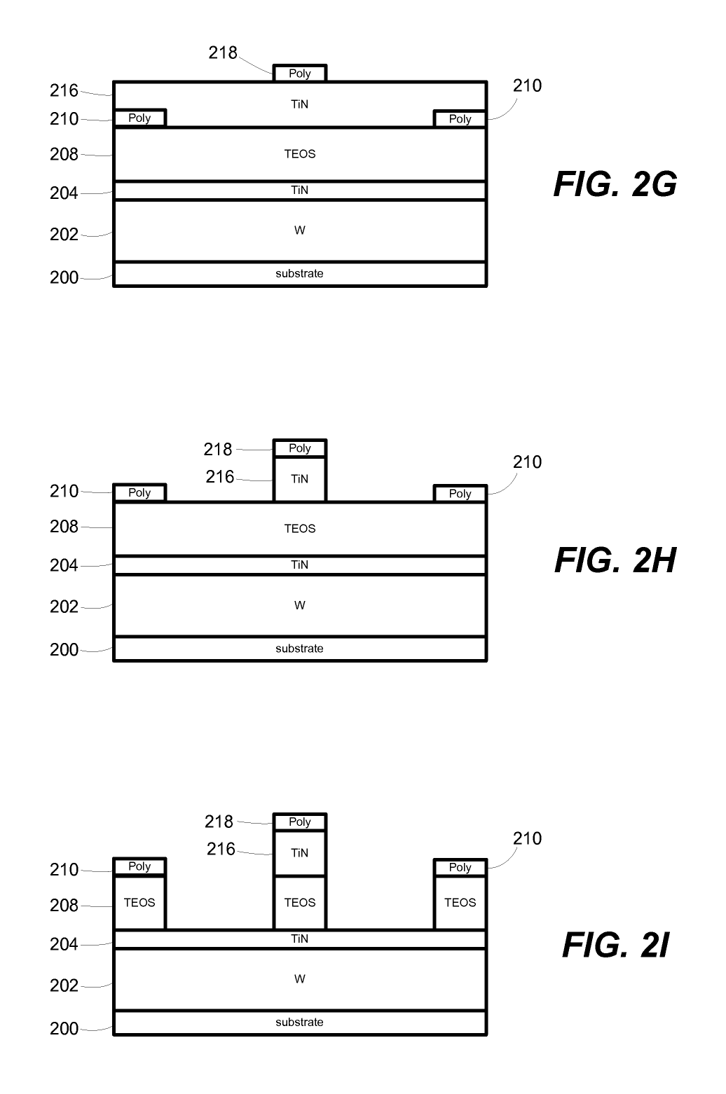

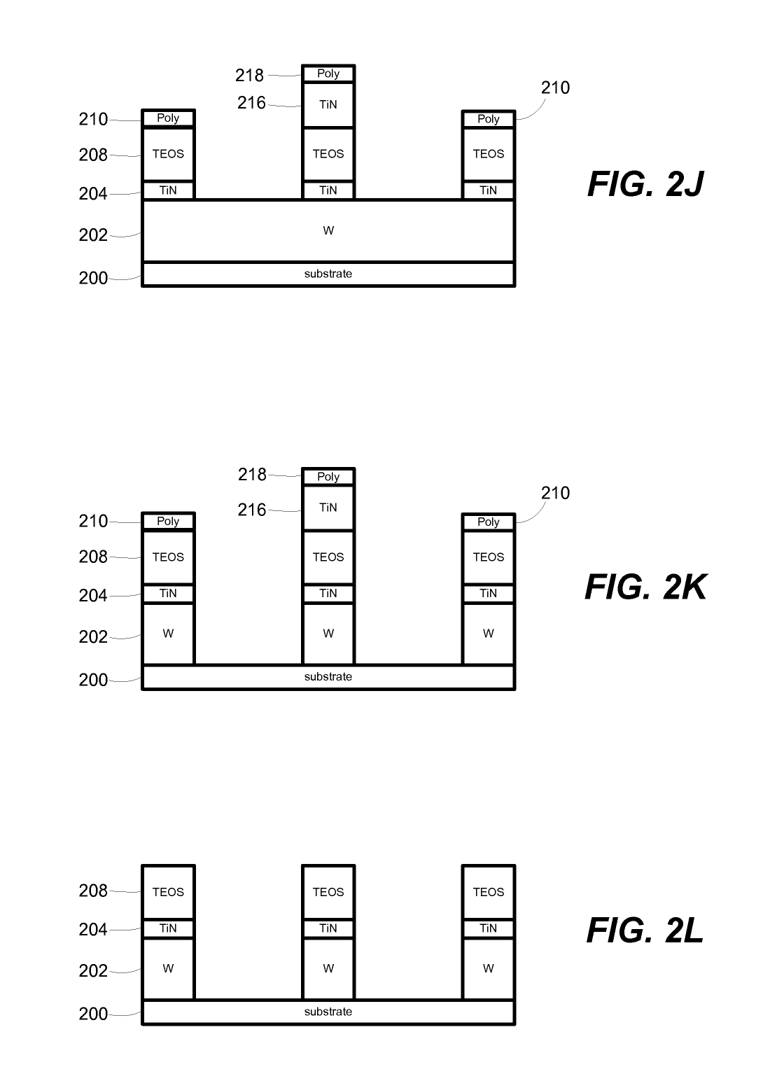

Turning now to FIGS. 2A through 2L, an example process for creating an array of conductors (e.g., word lines and/or bit lines for use in a three dimensional memory array) with an increased feature density is illustrated. Note that the drawings represent only a partial cross-sectional end view of only a small portion of a substrate with material layers that may be used to form one layer of conductors for a level of a three-dimensional memory array. In other words, even though formation of only three conductors is depicted, the present invention may be applied to forming any number of conductors in any orientation. Also note that while the process is illustrated as being performed on a substrate, the same process may be performed on top of one or more memory array levels so that conductor layers for additional levels of the memory array may be created by the process of the present invention.

With reference to FIG. 2A, a substrate 200 may be coated with multiple layers of films (e.g., tungsten (W) 202, tantalum nitride (TiN) 204, etc.) that may ultimately be employed to form conductors (e.g., word lines and/or bit lines). As indicated above, previously incorporated U.S. patent application Ser. No. 6,952,030 describes various methods of forming such layers. Although only one level or series of layers is depicted, the present invention may be applied to multiple levels of layers used to form a monolithic three dimensional memory array. Thus, in addition to layers that include materials to form conductors, layers that are used to form memory elements (not shown) and insulators (not shown) may also be present on or between the levels of layers. Further the layers may be inverted as compared to the layers depicted in FIG. 2A. Finally, it should be understood that many additional and alternative layers of different materials and thicknesses may be used to form the levels.

A layer of TEOS 208 may be formed on the conductor films. The TEOS layer 208 may have a thickness in the range of approximately 500 angstroms to approximately 4000 angstroms depending on the thickness of the wire material (films 202 & 204). Other materials such as SOG (spin on glass) and amorphous carbon may be used in place of TEOS.

On the TEOS layer 208, a layer of hardmask material 210 may be deposited. In some embodiments, a polycrystalline semiconductor material may be used as a hardmask 210 such as polysilicon, a polycrystalline silicon-germanium alloy, polygermanium or any other suitable material. In other embodiments, a material such as tungsten (W) may be used. The hardmask material layer 210 thickness may be of varying thickness, depending on the shrinking process parameters described below. In other words, in some embodiments, the hardmask material layer 210 may have an initial thickness in the range of approximately 500 angstroms to approximately 3000 angstroms depending on, for example, the concentrations of the components of the fluorozone process to be used.

To pattern the hardmask layer 210, photolithography layers such as Bottom Anti-Reflection Coating (BARC) 212 and patterned photoresist 214 may be deposited on the hardmask layer 210. The depths of the BARC 212 and photoresist 214 layers may be in the range of approximately 100 angstroms to approximately 2000 angstroms depending on the lithography process. Other resist or photolithography layers practicable and suitable for patterning the selected hardmask material 210 may be used.

According to the present invention, the photoresist 214 may be patterned using the highest feature density achievable with the process technology being used. Thus, if for example, 80 nm technology is used, the width of the elements of the photoresist pattern for forming features (e.g., diode pillars) may be 80 nm and the pitch, or spacing between the elements of the photoresist pattern, may also be 80 nm. Likewise, if 65 nm technology is used, the width of the elements of the photoresist pattern for forming features may be 65 nm and the pitch may also be 65 nm. Note that this is in contrast to convention double patterning methods where elements of the first photoresist pattern are required to be spaced apart further than the maximum density (e.g., minimum pitch) of the process technology being used.

Turning to FIG. 2B, a BARC/hardmask etch process applied to the structure in FIG. 2A results in the transfer of the photoresist pattern 214 to the hardmask 210. Any suitable BARC/hardmask etch process may be used. Many such processes are known in the art and thus, these processes are not described here.

Turning to FIG. 2C, the controlled shrinking of the hardmask 210 is achieved by exposing the patterned hardmask 210 to ozone mixed with a halogenated additive solution (e.g., a dilute mixture of hydrofluoric acid (HF) in water). Thus, for example, fluorozone may be used to shrink a polysilicon hardmask 210 that was initially formed with approximately 80 nm wide elements that are approximately 80 nm apart to a mask with approximately 45 nm wide elements that are approximately 160 nm apart, leaving room for inserting additional hardmask elements.

In some embodiments, fluorozone suitable for controllably shrinking hardmask materials may be formed using dilute hydrofluoric acid having a concentration in the range of approximately 0.03 Wt. % to approximately 0.2 Wt %. The ozone flow rate may be in the range of approximately 1 LPM to approximately 5 LPM with an O₃ concentration in the range of approximately 100 ppm to approximately 300 ppm. In some embodiments the dilute hydrofluoric acid may be heated to a temperature in the range of approximately 18° C. to approximately 35° C. The fluorozone process may be performed, for example, in a Raider® spray acid chamber manufactured by SemiTool Inc. of Kalispell, Mont. operating within a range of approximately 300 rpm to approximately 600 rpm. As indicated above, the initial hardmask 210 thickness may be of varying thickness, depending on the fluorozone process parameters. Also as indicated above, the controlled shrinking of the hardmask may be performed to reduce the hardmask's feature size by approximately 50%. This may be achieved by exposing the hardmask to the fluorozone process for a time in the range of approximately 5 seconds to approximately 0.25 hours. Further, in some embodiments, additional shrinkage may be achieved through longer exposure to the fluorozone process. In some embodiments, any native oxide on the surface of the hardmask may been removed prior to or during the exposure of the hardmask material to fluorozone.

Turning to FIG. 2D, an encapsulating or protective layer 216 may be deposited on the shrunken hardmask 210 to create a planarized surface upon which additional hardmask features may be formed. The protective layer 216 may include tantalum nitride, tungsten nitride, high-density plasma (HDP) oxide, TEOS, and/or spin-on-glass (SOG). The depth of the protective layer 216 may be in the range of approximately 200 angstroms to approximately 10,000 angstroms depending on the dimensions of layer 210.

Still with reference to FIG. 2D, an additional layer of hardmask material 218 is deposited on the protective layer 216. This additional layer of hardmask material 218 will be used to form the additional feature (and, in some embodiments, multiple features) between the two original hardmask features. As with the first hardmask layer 210, a polycrystalline semiconductor material such as polysilicon, a polycrystalline silicon-germanium alloy, polygermanium or any other suitable material may be used as the hardmask 218. In other embodiments, a material such as tungsten (W) may be used. The hardmask material layer 218 thickness may be of varying thickness, depending on the subsequent shrinking process parameters. In other words, in some embodiments, the hardmask material layer 218 may be deposited with an initial thickness in the range of approximately 500 angstroms to approximately 3000 angstroms depending on, for example, the concentrations of the components of the fluorozone process to be used.

Turning now to FIG. 2E, to pattern the hardmask layer 120, photolithography layers such as BARC 220 and patterned photoresist 224 may be deposited on the hardmask layer 218. The depths of the BARC 220 and photoresist 224 layers may be in the range of approximately 100 angstroms to approximately 2000 angstroms depending on the lithography process. Other resist or photolithography layers practicable and suitable for patterning the selected hardmask material 218 may be used. Note that the patterned photoresist 224 may be patterned using the original lithography mask used to pattern the prior layer of photoresist 214. In some embodiments, the original lithography mask may simply be laterally shifted an amount approximately equal to the nominal size of the process technology being used. Thus, if an 80 nm process is being employed, the lithography mask may be shifted by approximately 80 nm to properly locate the additional hardmask features 218 (FIG. 2F) between the original hardmask features 210.

Turning to FIG. 2F, a BARC/hardmask etch process applied to the structure in FIG. 2E results in the transfer of the photoresist pattern 224 to the hardmask 218. As above, any suitable BARC/hardmask etch process may be used. Many such processes are known in the art and thus, these processes are not described here.

Turning to FIG. 2G, the controlled shrinking of the hardmask 218 may be achieved in the same manner as described above. By exposing the patterned hardmask 218 to ozone mixed with a halogenated additive solution (e.g., a dilute mixture of hydrofluoric acid (HF) in water) the hardmask 218 features may be shrunk. For example, fluorozone may be used to shrink a polysilicon or tungsten hardmask 218 that was initially formed with approximately 80 nm wide elements that are approximately 80 nm apart to a mask with approximately 45 nm wide elements that are approximately 160 nm apart.

As above, in some embodiments, fluorozone suitable for controllably shrinking hardmask materials may be formed using dilute hydrofluoric acid having a concentration in the range of approximately 0.03 Wt. % to approximately 0.2 Wt %. The ozone flow rate may be in the range of approximately 1 LPM to approximately 5 LPM with an O₃ concentration in the range of approximately 100 ppm to approximately 300 ppm. In some embodiments the dilute hydrofluoric acid may be heated to a temperature in the range of approximately 18° C. to approximately 35° C. The fluorozone process may be performed, for example, in a Raider® spray acid chamber manufactured by SemiTool Inc. of Kalispell, Mont. operating within a range of approximately 300 rpm to approximately 600 rpm. Other similar tools maybe used. As indicated above, the initial hardmask 218 thickness may be of varying thickness, depending on the fluorozone process parameters. Also as indicated above, the controlled shrinking of the hardmask may be performed to reduce the hardmask's feature size by approximately 50%. This may be achieved by exposing the hardmask to the fluorozone process for a time in the range of approximately 5 seconds to approximately 0.25 hours. Further, in some embodiments, additional shrinkage may be achieved through longer exposure to the fluorozone process. In some embodiments, any native oxide on the surface of the hardmask may been removed prior to or during the exposure of the hardmask material to fluorozone.

Going from FIG. 2G to FIG. 2H, the protective layer 216 is etched out between the hardmask 210, 218 features down to the TEOS 208 layer in an oxide etch process. Going from FIG. 2H to FIG. 2I, the TEOS 208 layer is etched out between the hardmask 210, 218 features down to the top of conductor layers (e.g., tantalum nitride 204). Going from FIG. 2I to FIG. 2J, the tantalum nitride 204 layer is etched out between the hardmask 210, 218 features. Going from FIG. 2J to FIG. 2K, the tungsten layer 202 is etched out between the hardmask 210, 218 features and the hardmask 210, 218 is also etched away along with the remaining protective layer 216. The resulting structure is an array of conductors suitable for use in a memory array.

Although not shown, in some embodiments, after the conductor array has been formed, a dielectric layer may be deposited over the substrate 200 so as to fill the voids between the conductors. For example, approximately 200 to approximately 7000 angstroms of silicon dioxide may be deposited on the substrate 200 and planarized using chemical mechanical polishing or an etchback process to form a planar surface. Other dielectric materials such as silicon nitride, silicon oxynitride, low K dielectrics, etc., and/or other dielectric layer thicknesses may be used. Exemplary low K dielectrics include carbon doped oxides, silicon carbon layers, or the like.

The foregoing description discloses only exemplary embodiments of the invention. Modifications of the above disclosed apparatus and methods which fall within the scope of the invention will be readily apparent to those of ordinary skill in the art. For instance, although the present invention has been described primarily with regard to using FluorOzone to shrink the hardmask, other additives may be mixed with ozone to chemically shrink the mask.

Accordingly, while the present invention has been disclosed in connection with exemplary embodiments thereof, it should be understood that other embodiments may fall within the spirit and scope of the invention, as defined by the following claims.

The invention claimed is:

1. A method comprising:
forming a first hardmask at a maximum feature density of a process technology;
shrinking the first hardmask;
forming a second hardmask at the maximum feature density laterally shifted relative to the first hardmask;
shrinking the second hardmask; and
forming at least a portion of a memory array using the first and second hardmasks.

2. The method of claim 1 wherein forming the first and second hardmasks at the maximum feature density of a process technology includes forming hardmask features at a minimum feature size of the process technology.

3. The method of claim 3 wherein forming the first and second hardmasks at the maximum feature density of a process technology includes forming hardmask features at a minimum feature pitch of the process technology.

4. The method of claim 1 wherein forming the first and second hardmasks at the maximum feature density of a process technology includes forming hardmask features at a size of approximately 80 nm.

5. The method of claim 4 wherein forming the first and second hardmasks at the maximum feature density of a process technology includes forming hardmask features spaced at approximately 80 nm.

6. The method of claim 1 wherein forming the first and second hardmasks includes forming the hardmasks from a polycrystalline semiconductor material.

7. The method of claim 6 wherein forming the hardmasks from a polycrystalline semiconductor material includes forming the hardmasks from at least one of polysilicon, a polycrystalline silicon-germanium alloy and polygermanium.

8. The method of claim 1 wherein forming the first and second hardmasks includes forming the hardmasks from tungsten.

9. The method of claim 1 wherein shrinking the first and second hardmasks includes reducing a feature size of the hardmasks.

10. The method of claim 1 wherein shrinking the first and second hardmasks includes increasing a feature pitch of the hardmasks.

11. The method of claim 1 wherein shrinking the first and second hardmasks includes reducing a feature size of the hardmasks and increasing a feature pitch of the hardmasks by exposing the hardmasks to ozone mixed with a halogenated additive solution.

12. The method of claim 1 wherein shrinking the first and second hardmasks includes exposing the hardmasks to fluorozone.

13. The method of claim 1 wherein forming the second hardmask laterally shifted relative to the first hardmask includes forming the second hardmask laterally shifted by an amount that is approximately equal to a minimum feature size of the process technology.

14. The method of claim 1 wherein forming the second hardmask laterally shifted relative to the first hardmask includes forming the second hardmask laterally shifted by approximately 80 nm.

15. A memory array formed using the method of claim 1.

16. A method of forming a device array comprising:
forming a first mask over device layers;
shrinking the first mask;
forming a protective layer over the first mask;
forming a second mask shifted relative to the first mask; and
shrinking the second mask.

17. The method of claim 16 wherein forming the first and second masks includes forming mask features at a minimum feature size of a process technology being used.

18. The method of claim 17 wherein forming the first and second masks includes forming mask features at a minimum feature pitch of the process technology.

19. The method of claim 16 wherein forming the first and second masks includes forming hardmask features at a size of approximately 80 nm.

20. The method of claim 19 wherein forming the first and second masks includes forming mask features spaced at approximately 80 nm.

21. The method of claim 16 wherein forming the first and second masks includes forming the masks from a polycrystalline semiconductor material.

22. The method of claim 21 wherein forming the masks from a polycrystalline semiconductor material includes forming the masks from at least one of polysilicon, a polycrystalline silicon-germanium alloy and polygermanium.

23. The method of claim 16 wherein forming the first and second masks includes forming the masks from tungsten.

24. The method of claim 16 wherein shrinking the first and second masks includes reducing a feature size of the masks.

25. The method of claim 24 wherein reducing the feature size of the masks includes reducing the feature size of the masks by approximately 50%.

26. The method of claim 16 wherein shrinking the first and second masks includes increasing a feature pitch of the masks.

27. The method of claim 26 wherein increasing the feature pitch of the masks includes increasing the feature pitch of the masks by approximately 100%.

28. The method of claim 16 wherein shrinking the first and second masks includes reducing a feature size of the masks and increasing a feature pitch of the masks by exposing the masks to ozone mixed with a halogenated additive solution.

29. The method of claim 16 wherein shrinking the first and second masks includes exposing the masks to fluorozone.

30. The method of claim 16 wherein forming the second mask laterally shifted relative to the first mask includes forming the second mask laterally shifted by an amount that is approximately equal to a minimum feature size of the process technology.

31. The method of claim 16 wherein forming the second mask laterally shifted relative to the first mask includes forming the second mask laterally shifted by approximately 80 nm.

32. The method of claim 16 wherein forming the protective layer over the first mask includes forming a protective layer from tantalum nitride.

33. The method of claim 16 wherein forming the protective layer over the first mask includes forming a protective layer from at least one of tungsten nitride, high-density plasma (HDP) oxide, TEOS, and spin-on-glass (SOG).

34. A memory array formed using the method of claim 16.

35. A method comprising:
forming a first hardmask over a plurality of device layers;
exposing the first hardmask to ozone mixed with a halogenated additive;
forming a protective layer over the first hardmask;
forming a second hardmask on the protective layer shifted relative to the first hardmask; and
exposing the second hardmask to ozone mixed with the halogenated additive.

36. The method of claim 35 wherein forming the hardmasks includes using a single photolithography pattern to form both of the hardmasks.

37. The method of claim 36 wherein forming the first and second hardmasks includes forming the hardmasks from a polycrystalline semiconductor material.

38. The method of claim 36 wherein forming the hardmasks from a polycrystalline semiconductor material includes forming the hardmasks from at least one of polysilicon, a polycrystalline silicon-germanium alloy and polygermanium.

39. The method of claim 35 wherein forming the first and second masks includes forming the hardmasks from tungsten.

40. The method of claim 35 wherein exposing the first and second hardmasks to ozone mixed with a halogenated additive includes reducing a feature size of the hardmasks.

41. The method of claim 40 wherein reducing the feature size of the hardmasks includes reducing the feature size of the hardmasks to approximately 35% to approximately 65% of an original feature size.

42. The method of claim 35 wherein exposing the hardmasks to ozone mixed with the halogenated additive includes increasing a feature pitch of the hardmasks.

43. The method of claim 42 wherein increasing the feature pitch of the hardmasks includes increasing the feature pitch of the hardmasks by approximately 70% to approximately 130%.

44. The method of claim 35 wherein exposing the hardmasks to ozone mixed with the halogenated additive includes reducing a feature size of the hardmasks and increasing a feature pitch of the hardmasks.

45. The method of claim 35 wherein exposing the hardmasks to ozone mixed with the halogenated additive includes exposing the hardmasks to fluorozone.

46. The method of claim 35 wherein forming the second hardmask shifted relative to the first hardmask includes disposing the second hardmask such that corresponding features of the hardmasks would be adjacent each other if the corresponding features of the hardmasks were on a same plane.

47. The method of claim 35 wherein forming the second hardmask shifted relative to the first hardmask includes forming the second hardmask laterally shifted by approximately 80 nm.

48. The method of claim 35 wherein forming the protective layer over the first hardmask includes forming the protective layer from tantalum nitride.

49. The method of claim 35 wherein forming the protective layer over the first hardmask includes forming a protective layer from at least one of tungsten nitride, high-density plasma (HDP) oxide, TEOS, and spin-on-glass (SOG).

50. A memory array formed using the method of claim 35.

51. A method of forming an array of devices comprising:
forming a stack of a plurality of material layers;
forming a first hardmask over the plurality of material layers;
exposing the first hardmask to ozone mixed with a halogenated additive;
forming a protective layer over the first hardmask;
forming a second mask on the protective layer shifted relative to the first mask;
exposing the second hardmask to ozone mixed with the halogenated additive; and
etching the plurality of material layers to remove material not covered by either hardmask.

52. The method of claim 51 wherein forming the stack of material layers includes forming a stack including materials suitable for forming a diode.

53. The method of claim 51 wherein forming the stack of material layers includes forming a stack including materials suitable for forming a conductor.

54. The method of claim 51 wherein etching the plurality of material layers includes forming an array of vertical diodes.

55. The method of claim 51 wherein etching the plurality of material layers includes forming an array of conductors.

56. A memory array formed using the method of claim 51.
